(19) United States
(12) Patent Application Publication
(10) Pub. No.: US 2020/0075671 A1
(43) Pub. Date: Mar. 5, 2020

(54) MAGNETIC MEMORY DEVICE

(71) Applicant: TOSHIBA MEMORY CORPORATION, Tokyo (JP)

(72) Inventors: Jyunichi OZEKI, Seoul (KR); Masahiko NAKAYAMA, Kawasaki Kanagawa (JP); Hiroaki YODA, Kawasaki Kanagawa (JP); Eiji KITAGAWA, Kawasaki Kanagawa (JP); Takao OCHIAI, Yokkaichi Mie (JP); Minoru AMANO, Sagamihara Kanagawa (JP); Kenji NOMA, Seoul (KR)

(73) Assignee: TOSHIBA MEMORY CORPORATION, Tokyo (JP)

(21) Appl. No.: 16/678,316

(22) Filed: Nov. 8, 2019

Related U.S. Application Data
(62) Division of application No. 15/268,535, filed on Sep. 16, 2016.
(60) Provisional application No. 62/307,008, filed on Mar. 11, 2016.

(51) Int. Cl. H01L 27/22; H01L 43/08; H01L 43/10

(52) U.S. Cl. CPC H01L 27/228; H01L 43/10; H01L 43/08

(57) ABSTRACT

According to one embodiment, a magnetic memory device includes a first magnetic layer having a variable magnetization direction, and including a first main surface and a second main surface located opposite to the first main surface, a second magnetic layer provided on a first main surface side of the first magnetic layer, and having a fixed magnetization direction, and a nonmagnetic layer provided between the first magnetic layer and the second magnetic layer, wherein a saturation magnetization of a part of the first magnetic layer which is located close to the first main surface is higher than a saturation magnetization of a part of the first magnetic layer which is located close to the second main surface.

### CROSS-REFERENCE TO RELATED APPLICATIONS

This application is a Divisional Application of U.S. application Ser. No. 15/268,535, filed Sep. 16, 2016, which claims the benefit of U.S. Provisional Application No. 62/307,008, filed Mar. 11, 2016, the entire contents of both of which are incorporated herein by reference.

### FIELD

Embodiments described herein relate generally to a magnetic memory device.

### BACKGROUND

Magnetic memory devices (semiconductor integrated circuit devices) have been proposed in which magnetoresistive elements and MOS transistors are integrated on a semiconductor substrate.

In those magnetic memory devices, the more minute the elements, the smaller the current produced by the MOS transistors. It is therefore necessary to reduce write current to the magnetoresistive elements.

However, conventionally, write current to magnetoresistive elements cannot be easily reduced.

### BRIEF DESCRIPTION OF THE DRAWINGS

FIG. 1 is a cross-sectional view schematically showing a configuration of a magnetic memory device according to each of first and second embodiments.

FIG. 2 is related to the first embodiment, and is a view showing a relationship between the density of write current to a magnetoresistive element and the reversal probability of the magnetization direction of a storage layer.

FIG. 3 is related to the first embodiment, and is a view showing a relationship between effective magnetic anisotropy energy and write current.

FIG. 4 is related to the first embodiment, and is a view showing a relationship between effective magnetic anisotropy energy and a reversal probability distribution steepening factor.

FIG. 5 is related to the first embodiment, and is a cross-sectional view schematically showing a first concrete configuration example of the storage layer of the magnetoresistive element.

FIG. 6 is related to the first embodiment, and is a cross-sectional view schematically showing a second concrete configuration example of the storage layer of the magnetoresistive element.

FIG. 7 is related to the first embodiment, and is a cross-sectional view schematically showing a third concrete configuration example of the storage layer of the magnetoresistive element.

FIG. 8 is related to the first embodiment, and is a view showing a write current reduction effect.

FIG. 9 is related to the second embodiment, and is a cross-sectional view schematically showing a configuration example of a storage layer of a magnetoresistive element.

FIG. 10 is related to the second embodiment, and is a cross-sectional view schematically showing a modification of the storage layer of the magnetoresistive element.

FIG. 11 is a cross-sectional view schematically showing a configuration of a magnetic memory device (semiconductor integrated circuit device) to which the magnetoresistive elements according to the first and second embodiments are each applied.

### DETAILED DESCRIPTION

In general, according to one embodiment, a magnetic memory device includes: a first magnetic layer having a variable magnetization direction, and including a first main surface and a second main surface located opposite to the first main surface; a second magnetic layer provided on a first main surface side of the first magnetic layer, and having a fixed magnetization direction; and a nonmagnetic layer provided between the first magnetic layer and the second magnetic layer, wherein saturation magnetization of part of the first magnetic layer which is located close to the first main surface is higher than saturation magnetization of part of the first magnetic layer which is located close to the second main surface.

Embodiments will be described with reference to the accompanying drawings.

### First Embodiment

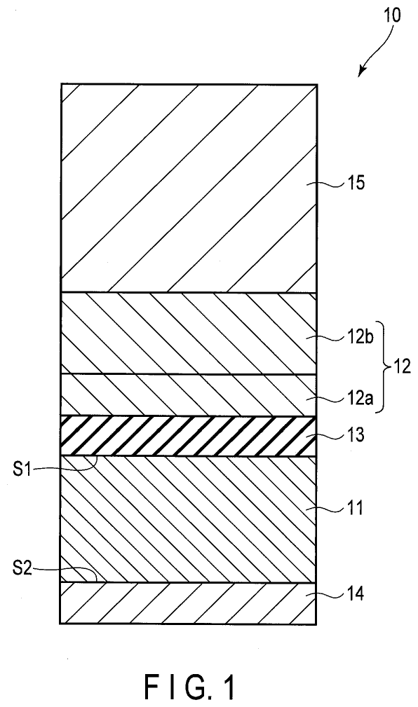

FIG. 1 is a cross-sectional view schematically showing the structure of a magnetic memory device according to a first embodiment. To be more specific, it is a cross-sectional view schematically showing the structure of a magnetoresistive element. It should be noted that the magnetoresistive element is also referred to as a magnetic tunnel junction (MTJ) element.

A magnetoresistive element (MTJ element) 10 is a spin-transfer-torque (STT) magnetoresistive element having perpendicular magnetization, and comprises a storage layer (first magnetic layer) 11, a reference layer (second magnetic layer) 12, a tunnel barrier layer (nonmagnetic layer) 13, an under layer 14 and a shift canceling layer (third magnetic layer) 15. To be more specific, the magnetoresistive element 10 has a stacked structure in which the under layer 14, the storage layer 11, the tunnel barrier layer 13, the reference layer 12 and the shift canceling layer 15 are stacked together.

The storage layer (first magnetic layer) 11 is a ferromagnetic layer having a variable magnetization direction perpendicular to its main surfaces, and a first main surface S1 and a second main surface S2 located opposite to the first main surface S1. In the first embodiment, saturation magnetization Ms close to the first main surface S1 of the storage layer 11 is higher than that close to the second main surface S2 of the storage layer 11. A storage layer 11 contains at least iron (Fe) and boron (B). In the first embodiment, the storage layer 11 further contains cobalt (Co) in addition to iron (Fe) and boron (B). More specifically, the storage layer 11 is formed of CoFeB. It will be concretely described later what structure the storage layer 11 has in order to achieve the above.

The reference layer (second magnetic layer) 12 is located on a first main surface S1 side of the storage layer (first magnetic layer) 11, and is a ferromagnetic layer having a fixed magnetization direction perpendicular to the above main surface. The reference layer 12 includes a lower portion 12a provided on the tunnel barrier layer 13 and an upper portion 12b provided on the shift canceling layer 15. A lower portion 12a contains at least iron (Fe) and boron (B). In the first embodiment, the lower portion 12a further contains cobalt (Co) in addition to iron (Fe) and boron (B). To be more specific, the lower portion 12a is formed of CoFeB. The upper portion 12b contains cobalt (Co) and an element selected from platinum (Pt), nickel (Ni) and palladium (Pd). To be more specific, the upper portion 12b is formed of CoPt, CoNi or CoPd. Between the lower portion 12a and the upper portion 12b, an intermediate portion formed of predetermined metal may be provided.

The tunnel barrier layer (nonmagnetic layer) 13 is provided between the storage layer 11 and the reference layer 12, and also in contact with the first main surface S1 of the storage layer 11 and the lower portion 12a of the reference layer 12. The tunnel barrier layer 13 contains magnesium (Mg) and oxygen (O). To be more specific, the tunnel barrier layer 13 is formed of MgO.

The under layer 14 is provided on a lower side of the storage layer 11, and in contact with the second main surface S2 of the storage layer 11. The under layer 14 is formed of a nitrogen compound or an oxygen compound, such as magnesium oxide (MgO), magnesium nitride (MgN), zirconium nitride (ZrN), niobium nitride (NbN), silicon nitride (SiN), aluminum nitride (AlN), hafnium nitride (HfN), tantalum nitride (TaN), tungsten nitride (WN), chromium nitride (CrN), molybdenum nitride (MoN), titanium nitride (TiN) or vanadium nitride (VN). Also, it may be formed of a ternary compound selected and obtained from the above elements (Mg, Zr, Nb, Si, Al, Hf, Ta, W, Cr, Mo, Ti, V, etc.). For example, it may be formed of titanium aluminum nitride (AlTiN) or the like.

The shift canceling layer (third magnetic layer) 15 is a ferromagnetic layer having a fixed magnetization direction perpendicular to its main surfaces. The magnetization direction of the shift canceling layer 15 is opposite to that of the reference layer 12, and the shift canceling layer 15 has a function of canceling a magnetic field applied from the reference layer 12 to the storage layer 11. The shift canceling layer 15 contains cobalt (Co) and an element selected from platinum (Pt), nickel (Ni) and palladium (Pd). To be more specific, the shift canceling layer 15 is formed of CoPt, CoNi or CoPd.

When the magnetization direction of the storage layer 11 is parallel to that of the reference layer 12, the resistance of the stacked structure (the resistance of the magnetoresistive element 10) is lower than that when the magnetization direction of the storage layer 11 is antiparallel to that of the reference layer 12. That is, when the magnetization direction of the storage layer 11 is parallel to that of the reference layer 12, the magnetoresistive element 10 is in a low-resistance state, and when the magnetization direction of the storage layer 11 is antiparallel to that of the reference layer 12, the magnetoresistive element 10 is in a high-resistance state. Therefore, the magnetoresistive element 10 can store binary data (0 or 1) in accordance with the resistance state (low-resistance state or high-resistance state). Furthermore, the resistance state (low- or high-resistance state) of the magnetoresistive element 10 can be set in accordance with the direction in which write current flows in the magnetoresistive element 10.

As described above, in the magnetoresistive element 10 according to the first embodiment, the saturation magnetization Ms of part of the storage layer 11 which is located close to the first main surface S1 thereof is higher than that of part of the storage layer 11 which is located close to the second main surface S2 thereof. By virtue of the above structure, the effective magnetic anisotropy energy of the part of the storage layer 11 which is located close to the first main surface S1 thereof can be made smaller than or equal to that of the part of the storage layer 11 which is located close to the second main surface S2 thereof. That is, the effective magnetic anisotropy energy of part of the storage layer 11 which is located close to an interface between the storage layer 11 and the tunnel barrier layer 13 can be made smaller than or equal to that of part of the storage layer 11 which is located close to an interface between the storage layer 11 and the under layer 14.

In the first embodiment, it is possible to reduce the write current to the magnetoresistive element. Also, by virtue of the above structure, the reversal probability characteristic of the magnetization direction of the storage layer 11 can be made steep, thereby also enabling the write current to be reduced. Therefore, in the first embodiment, even if elements are made more minute, it is possible to reliably perform writing to the magnetoresistive element.

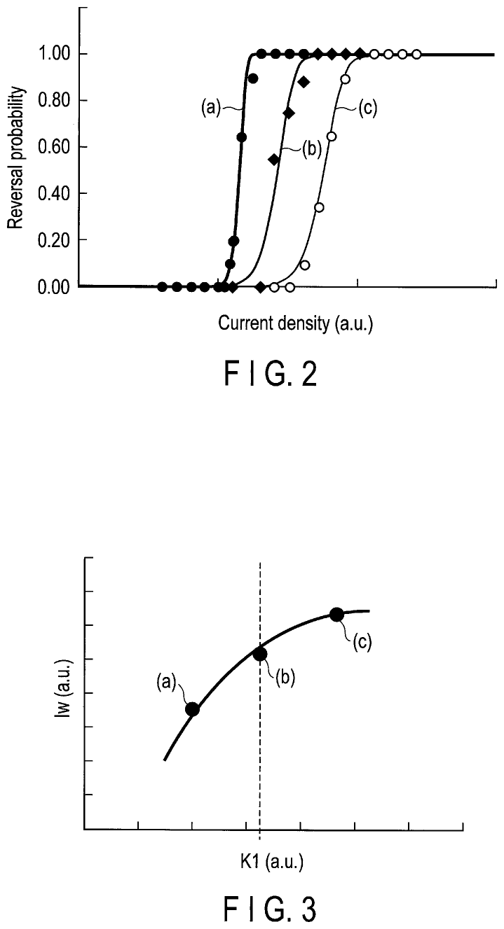

FIG. 2 is a view showing a relationship between the density of write current to the magnetoresistive element and the reversal probability of the magnetization direction of the storage layer 11. The storage layer 11 comprises three layers having different effective magnetic anisotropy energy (the upper portion [provided on a tunnel barrier layer 13 side], the lower portion [provided on an under layer 14 side] and the intermediate portion [between the upper portion and the lower portion]). In sample (a), the effective magnetic anisotropy energy of the upper portion is lower than that of the lower portion; in sample (b), the effective magnetic anisotropy energy of the upper portion is equal to that of the lower portion; and in sample (c), the effective magnetic anisotropy energy of the upper portion is higher than that of the lower portion. The intermediate portion is formed of a nonmagnetic metal layer, and its effective magnetic anisotropy energy is zero.

As can be seen from FIG. 2, the switching current density decreases from sample (c) to sample (a), and the steepness of the reversal characteristic increases from sample (c) to sample (a). Therefore, it is possible to reduce the write current to the magnetoresistive element by causing effective magnetic anisotropy energy K1 of the tunnel barrier layer 13 side (the first main surface S1 side of the storage layer 11) to be smaller than or equal to effective magnetic anisotropy energy K3 of the under layer 14 side (the second main surface S2 side of the storage layer 11).

FIG. 3 is a view showing a relationship between effective magnetic anisotropy energy K1 and write current Iw in the case where a write error rate (WER) is 1×10⁻¹², with respect to samples (a), (b) and (c). As can be seen from FIG. 2, of write current Iw of samples (a) to (c), write current Iw of sample (c) is the largest, that of sample (b) is intermediate, and that of sample (a) is the smallest. Therefore, it can be understood also from the result shown in FIG. 3 that the write current can be reduced as described above.

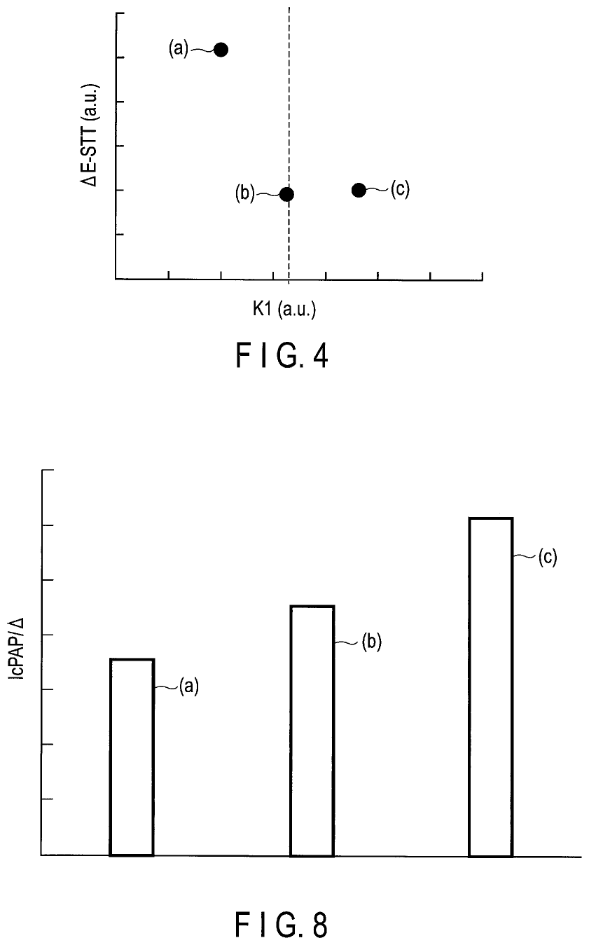

FIG. 4 is a view showing a relationship between effective magnetic anisotropy energy K1 and a reversal probability distribution steepening factor ΔE with respect to samples (a), (b) and (c). As can be seen from FIG. 4, in sample (a), the steepening factor ΔE is great. Therefore, it can be understood also from the result shown in FIG. 4 that the write current can be reduced.

The following explanation is given with respect to a basic structure for causing the saturation magnetization Ms of the part of the storage layer 11 which is located close to the first main surface S1 thereof to be higher than that of the part of the storage layer 11 which is located close to the second main surface S2 thereof, i.e., a basic structure for causing the effective magnetic anisotropy energy of the part of the storage layer 11 which is close to the first main surface S1 to be smaller than or equal to that of the part of the storage layer 11 which is close to the second main surface S2 of the storage layer 11.

In a first basic structure, the concentration of iron (Fe) in the part of the storage layer 11 which is close to the first main surface S1 thereof is lower than that of iron (Fe) in the part of the storage layer 11 which is close to the second main surface S2 thereof. In other words, the composition ratio of iron (Fe) in the part of the storage layer 11 which is close to the first main surface S1 is lower than that of iron (Fe) in the part of the storage layer 11 which is close to the second main surface S2. That is, in the case where the storage layer 11 is formed of a CoFeB layer, the ratio of Fe in the CoFeB layer in the above part close to the first main surface S1 is lower than that in the part close to the second main surface S2.

In a second basic structure, the concentration of boron (B) in the part of the storage layer 11 which is close to the first main surface S1 thereof is lower than that of boron (B) in the part of the storage layer 11 which is close to the second main surface S2 thereof. That is, in the case where the storage layer 11 is formed of a CoFeB layer or an FeB layer, the concentration of B in the above part close to the first main surface S1 is lower than that in the part close to the second main surface S2.

In a third basic structure, the storage layer 11 further contains an added element selected from molybdenum (Mo) and tungsten (W), and the concentration of the added element in the part of the storage layer 11 which is close to the first main surface S1 thereof is lower than that of the added element in the part of the storage layer 11 which is close to the second main surface S2 thereof. That is, in the case where the storage layer 11 is formed of a CoFeB layer or an FeB layer, and further contains the above added element, the concentration of the added element in the above part close to the first main surface S1 is lower than that in the part close to the second main surface S2.

It should be noted that the storage layer 11 may be formed by combining two or more of the first to third basic structures.

Next, concrete configuration examples of the storage layer 11 in the magnetic memory device according to the first embodiment will be explained.

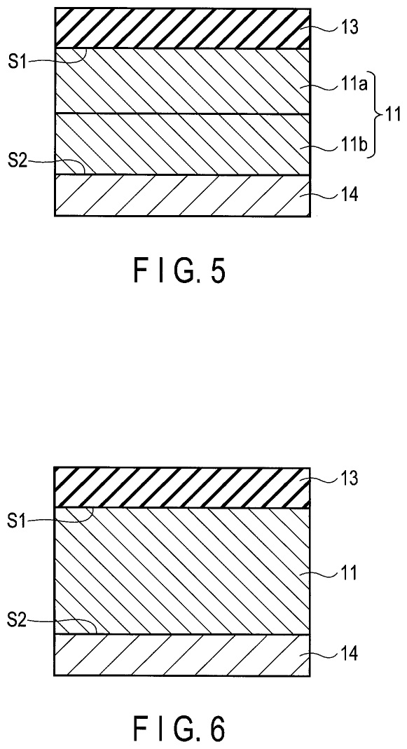

FIG. 5 is a cross-sectional view schematically showing a first concrete configuration example of the storage layer 11. As shown in FIG. 5, the storage layer 11 includes a first sub-magnetic layer 11a including a region close to the first main surface S1 and having first saturation magnetization Ms1, and a second sub-magnetic layer 11b including a region close to the second main surface S2 and having second saturation magnetization Ms2 lower than the first saturation magnetization MS1. To be more specific, based on the above first to third basic structures, the storage layer 11 including the first sub-magnetic layer 11a and the second sub-magnetic layer 11b can be formed.

FIG. 6 is a cross-sectional view schematically showing a second concrete configuration example of the storage layer 11. In the second concrete configuration example, the storage layer 11 has a structure whose saturation magnetization gradually increases from the second main surface S2 toward the first main surface S1. To be more specific, based on the first to third basic structures, the storage layer 11 having such a structure can be formed.

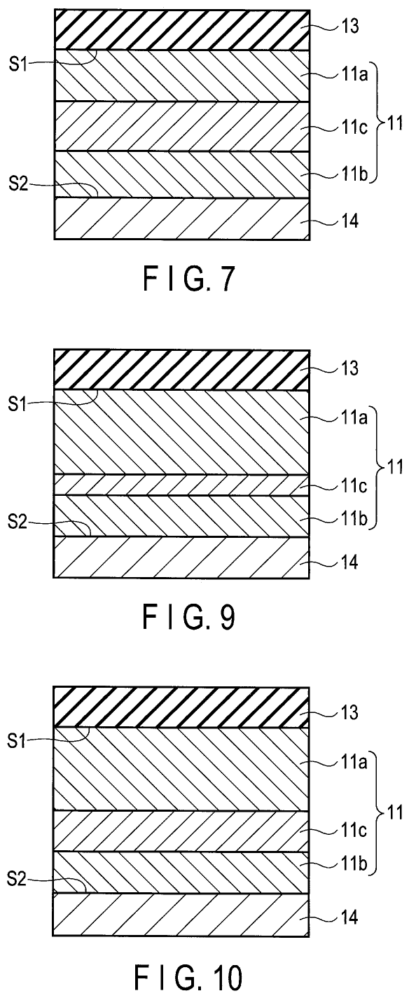

FIG. 7 is a cross-sectional view schematically showing a third concrete configuration example of the storage layer 11. In the third concrete configuration example, in addition to the first sub-magnetic layer 11a and the second sub-magnetic layer 11b, the storage layer 11 further includes a sub-nonmagnetic layer 11c provided between the first sub-magnetic layer 11a and the second sub-magnetic layer 11b. The first sub-magnetic layer 11a and the second sub-magnetic layer 11b have the same structures as those of the first concrete configuration example. It is preferable that the sub-nonmagnetic layer 11c have a thickness of 1 nm or more. Also, it is preferable that the sub-nonmagnetic layer 11c be formed of material containing at least one element selected from B, Mg, Al, Si, Ti, V, Cr, Mn, Cu, Zn, Zr, Nb, Mo, Ru, Rh, Pd, Ag, Cd, In, Sn, Hf, Ta, W, Re, Os, Ir, Pt and Au. To be more specific, the sub-nonmagnetic layer 11c may be formed of at least one of the above elements, or a nitride or oxide formed of at least one of the above elements.

It is possible to weaken exchange coupling energy Jex by providing the sub-nonmagnetic layer 11c between the first sub-magnetic layer 11a and the second sub-magnetic layer 11b, as described above. As a result, the write current to the magnetoresistive element can be reduced. Also, by setting the thickness of the sub-nonmagnetic layer 11c at 1 nm or more, the exchange coupling energy Jex can be further weakened, and the write current can be further reduced.

FIG. 8 is a view showing a write current reduction effect. IcPAP/Δ represented by the vertical axis is an index representing the write current reduction effect. IcPAP corresponds to write current (write current necessary for changing the magnetization direction of the storage layer 11 with respect to the reference layer 12, from the parallel state to the antiparallel state), and A corresponds to an information holding function of the magnetoresistive element. It is shown that the smaller the value IcPAP/Δ, the greater the write current reduction effect. (a) corresponds to the case where the thickness of the sub-nonmagnetic layer 11c is great (the exchange coupling is weak), (b) corresponds to the case where the thickness of the sub-nonmagnetic layer 11c is small (the exchange coupling is strong), and (c) corresponds to the case where the sub-nonmagnetic layer 11c is not provided. As can be seen from FIG. 8, in the case where the thickness of the sub-nonmagnetic layer 11c is great (a), the value IcPAP/Δ is the smallest, and the write current reduction effect is great. Therefore, it is possible to reduce the write current to the magnetoresistive element by providing the sub-nonmagnetic layer 11c between the first sub-magnetic layer 11a and the second sub-magnetic layer 11b.

### Second Embodiment

A second embodiment will be explained. Since basic matters of the second embodiment are the same as those of the first embodiment, the matters described with respect to the first embodiment will be omitted.

FIG. 9 is a cross-sectional view schematically showing a configuration example of a storage layer 11 of a magnetoresistive element according to the second embodiment. It should be noted that the basic structure of the magnetoresistive element is the same as that of the first embodiment as shown in FIG. 1. Also, the storage layer (first magnetic layer) 11, a reference layer (second magnetic layer) 12, a tunnel barrier layer (nonmagnetic layer) 13, an under layer 14 and a shift canceling layer (third magnetic layer) which are included in the magnetoresistive element are formed of the same materials as those of the first embodiment.

As shown in FIG. 9, in the second embodiment, the storage layer (first magnetic layer) 11 comprises a first sub-magnetic layer 11a including a region close to a first main surface S1, a second sub-magnetic layer 11b including a region close to a second main surface S2, and a sub-nonmagnetic layer 11c provided between the first sub-magnetic layer 11a and the second sub-magnetic layer 11b; and the first sub-magnetic layer 11a is thicker than the second sub-magnetic layer 11b.

As described above, in the magnetoresistive element according to the second embodiment, the first sub-magnetic layer 11a including the region close to the first main surface S1 of the storage layer 11 is thicker than the second sub-magnetic layer 11b including the region close to the second main surface S2 of the storage layer 11. By virtue of such a structure, the effective magnetic anisotropy energy of the vicinity of the first main surface S1 of the storage layer 11 can be made smaller than or equal to that of the vicinity of the second main surface S2 of the storage layer 11. That is, the effective magnetic anisotropy energy of part of the storage layer 11 which is located close to an interface between the storage layer 11 and a tunnel barrier layer 13 can be made smaller than or equal to that of part of the storage layer 11 which is located close to an interface between the storage layer 11 and an under layer 14.

Therefore, in the second embodiment also, the write current to the magnetoresistive element can be reduced, and the reversal probability characteristic of the magnetization direction of the storage layer 11 can be made steep, as in the first embodiment. Thus, in the second embodiment also, even if elements are made more minute, it is possible to reliably perform writing to the magnetoresistive element, as in the first embodiment.

FIG. 10 is a cross-sectional view schematically showing a modification of the storage layer 11 of the magnetoresistive element according to the second embodiment. In the modification, a sub-nonmagnetic layer 11c is made to have a thickness of 1 nm or more. Also, the sub-nonmagnetic layer 11c is formed of the same material as that of the third concrete example of the first embodiment. In such a manner, since the sub-nonmagnetic layer 11c having a thickness of 1 nm or more is provided between first and second sub-magnetic layers 11a and 11b, it is possible to weaken the exchange coupling energy, and reduce the write current to the magnetoresistive element, as in the third concrete configuration example of the first embodiment.

It should be noted that in the above first and second embodiments, the storage layer 11, the tunnel barrier layer 13, the reference layer 12 and the shift canceling layer 15 are stacked from a lower-layer side to an upper-layer side; however, the storage layer 11, the tunnel barrier layer 13, the reference layer 12 and the shift canceling layer 15 may be stacked from the upper-layer side to the lower-layer side.

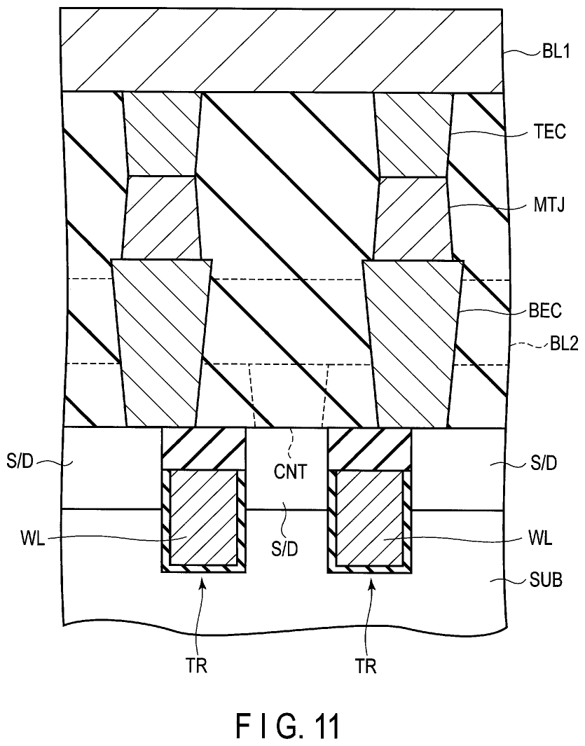

FIG. 11 is a cross-sectional view schematically showing a configuration of a magnetic memory device (semiconductor integrated circuit device) to which the magnetoresistive elements according to the above first and second embodiments are each applied.

As shown in FIG. 11, buried gate MOS transistors TR are formed in a semiconductor substrate SUB. A gate electrode of a MOS transistor TR is used as a word line WL. One of source/drain regions S/D of the MOS transistor TR is connected to a bottom electrode BEC, and the other is connected to a contact CNT.

On the bottom electrode BEC, a magnetoresistive element MTJ is formed, and on the magnetoresistive element MTJ, a top electrode TEC is formed. To the top electrode TEC, a first bit line BL1 is connected. To the contact CNT, a second bit line BL2 is connected.

By applying the magnetoresistive element described with respect to each of the first and second embodiments to such a magnetic memory device (semiconductor integrated circuit) as shown in FIG. 11, the write current to the magnetoresistive element can be reduced, and even if elements are made more minute, it is possible to reliably perform writing to the magnetoresistive element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory device comprising:
a first magnetic layer having a variable magnetization direction, and including a first main surface and a second main surface located opposite to the first main surface;
a second magnetic layer provided on a first main surface side of the first magnetic layer, and having a fixed magnetization direction; and
a nonmagnetic layer provided between the first magnetic layer and the second magnetic layer,
wherein:
a saturation magnetization of a part of the first magnetic layer which is located close to the first main surface is higher than a saturation magnetization of a part of the first magnetic layer which is located close to the second main surface,
the first magnetic layer includes a first sub-magnetic layer, a second sub-magnetic layer, and a sub-nonmagnetic layer provided between the first sub-magnetic layer and the second sub-magnetic layer,
the first sub-magnetic layer includes a region close to the first main surface and has a first saturation magnetization,
the second sub-magnetic layer includes a region close to the second main surface and has a second saturation magnetization lower than the first saturation magnetization, and
the first sub-magnetic layer and the second sub-magnetic layer are in contact with the sub-nonmagnetic layer.

2. The device of claim 1, wherein the first magnetic layer contains iron (Fe) and boron (B).

3. The device of claim 2, wherein the first magnetic layer further contains cobalt (Co).

4. The device of claim 3, wherein a concentration of iron (Fe) in the part of the first magnetic layer which is located close to the first main surface is lower than a concentration of iron (Fe) in the part of the first magnetic layer which is located close to the second main surface.

5. The device of claim 2, wherein a concentration of boron (B) in the part of the first magnetic layer which is located close to the first main surface is lower than a concentration of boron (B) in the part of the first magnetic layer which is located close to the second main surface.

6. The device of claim 2, wherein the first magnetic layer further contains an added element selected from molybdenum (Mo) and tungsten (W), and
a concentration of the added element in the part of the first magnetic layer which is located close to the first main surface is lower than a concentration of the added element in the part of the first magnetic layer which is located close to the second main surface.

7. The device of claim 1, wherein the nonmagnetic layer contains magnesium (Mg) and oxygen (O).

8. The device of claim 1, wherein the sub-nonmagnetic layer has a thickness of 1 nm or more.

9. The device of claim 1, wherein the first sub-magnetic layer is thicker than the second sub-magnetic layer.

10. The device of claim 1, wherein the first magnetic layer has a saturation magnetization which increases from the second main surface toward the first main surface.

11. The device of claim 1, wherein an effective magnetic anisotropy energy of the part of the first magnetic layer which is located close to the first main surface is smaller than or equal to an effective magnetic anisotropy energy of the part of the first magnetic layer which is located close to the second main surface.
